(19) United States
(12) Patent Application Publication
(10) Pub. No.: US 2026/0139173 A1
(43) Pub. Date: May 21, 2026

(54) POLISHING SLURRY AND METHOD OF MANUFACTURING SEMICONDUCTOR DEVICE

(71) Applicant: SAMSUNG ELECTRONICS CO., LTD., Suwon-si (KR)

(72) Inventors: Fedosya KALININA, Suwon-si (KR); Sang Soo JEE, Suwon-si (KR); Yoonseok KO, Suwon-si (KR); Hyune Jea LEE, Suwon-si (KR); Juhyung LIM, Suwon-si (KR)

(21) Appl. No.: 19/387,200

(22) Filed: Nov. 12, 2025

(30) Foreign Application Priority Data
Nov. 21, 2024 (KR) 10-2024-0167456
Nov. 10, 2025 (KR) 10-2025-0168734

(51) Int. Cl. C09K 3/14; H01L 21/3205; H01L 21/321; H01L 21/768; H01L 23/532

(52) U.S. Cl. CPC C09K 3/1463; H10P 14/412; H10P 52/403; H10W 20/056; H10W 20/062; H10W 20/4441

(57) ABSTRACT

polishing slurry including an abrasive, an oxidizing agent, and a first histidine derivative including a substituted or unsubstituted cyclic imide group, optionally a second histidine derivative including a substituted or unsubstituted amic acid group, or a combination thereof. A method of manufacturing a semiconductor device using the same is described.

### CROSS-REFERENCE TO RELATED APPLICATION

This U.S. nonprovisional patent application is based on and claims priorities under 35 U.S.C. § 119 to Korean Patent Applications No. 10-2024-0167456 and 10-2025-0168734 filed in the Korean Intellectual Property Office on Nov. 21, 2024 and Nov. 10, 2025, respectively, the contents of which are incorporated herein by reference.

### BACKGROUND

### 1. Field

The present disclosure relates to a polishing slurry and a method of manufacturing a semiconductor device.

### 2. Description of the Related Art

Recently, due to the miniaturization of electronic devices and the subsequent miniaturization of integrated circuits, various methods of forming microstructures such as metal wires with a width of several nanometers, contact holes, or shallow trench isolations have been studied.

In forming such microstructures, polishing processes may be performed to make the surface of the microstructures flat and smooth, and chemical mechanical polishing (CMP) may be one of the polishing processes. Chemical mechanical polishing is a process of providing a polishing slurry including an abrasive between a semiconductor substrate including an object to be polished and a polishing pad to planarize the surface of the semiconductor substrate.

### SUMMARY

In order to improve a chemical mechanical polishing performance, it may be required to increase the polishing rate of the object to be polished such as a metal, while reducing or preventing loss or defects in the object to be polished. For example, dishing is a defect or loss in which the center of an object is concave. Dishing may be caused by corrosion or over-etching.

An embodiment provides a polishing slurry capable of polishing, i.e., removing at least a portion of a surface of an object to be polished at a high polishing rate and reducing or preventing loss or defects in the object to be polished due to excessive corrosion or over-etching. The defects may be metal oxides or other oxidized compounds.

An embodiment provides a method of manufacturing a semiconductor device using the polishing slurry.

According to an embodiment, a polishing slurry includes an abrasive, an oxidizing agent, and a first histidine derivative including a substituted or unsubstituted cyclic imide group.

The first histidine derivative may be represented by Chemical Formula 1-1.

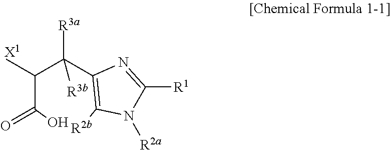

In Chemical Formula 1-1,
X¹ may be a substituted or unsubstituted cyclic imide group,
R¹, R^{2a}, R^{2b}, R^{3a}, and R^{3b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} may each independently be present or any two adjacent R¹, R^{2a}, R^{2b}, R^{3a}, and R^{3b} may be bonded to form a ring.
X¹ may be represented by any one of Chemical Formulas A to C.

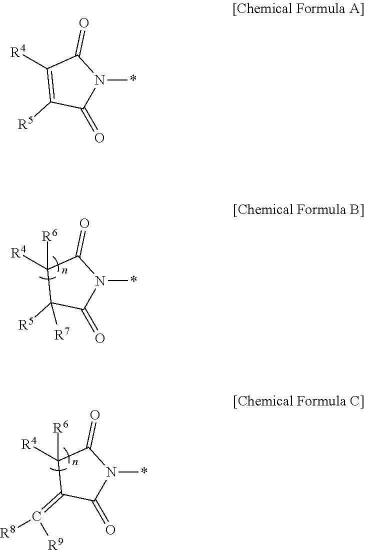

In Chemical Formulas A to C,
R⁴ to R⁹ may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R⁴ to R⁹ may each independently be present or any two adjacent R⁴ to R⁹ them may be bonded to form a ring,
n may be an integer of 1 to 5, and
* may be a linking point with Chemical Formula 1-1.
X¹ may be represented by any one of Chemical Formulas B-1 to B-5.

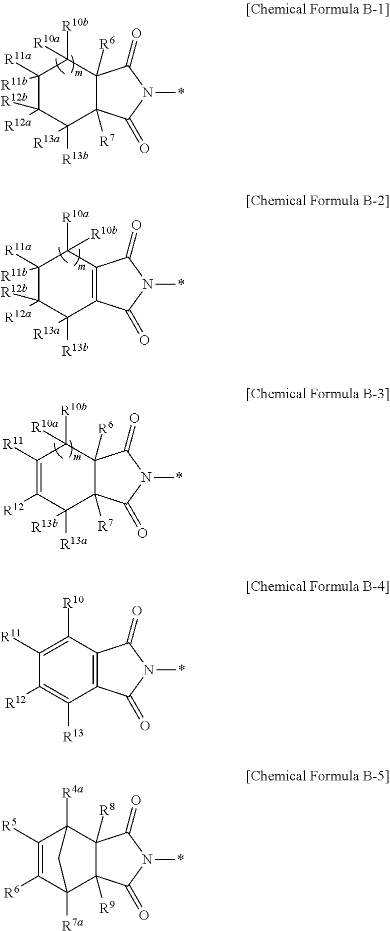

In Chemical Formulas B-1 to B-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be present or any adjacent two the foregoing R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may be bonded to form a ring,
m may be an integer of 0 to 5, and
* may be a linking point with Chemical Formula 1-1.

The polishing slurry may further include a second histidine derivative including a substituted or unsubstituted amic acid group.

The second histidine derivative may be represented by Chemical Formula 1-2.

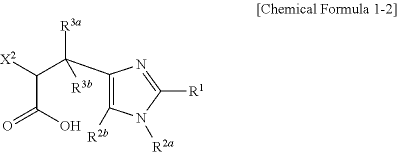

In Chemical Formula 1-2,
X² may be a substituted or unsubstituted amic acid group,
R¹, R^{2a}, R^{2b}, R^{3a}, and R^{3b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group, and
R¹, R^{2a}, R^{2b}, R^{3a}, and R^{3b} may each independently be present or any two adjacent R¹, R^{2a}, R^{2b}, R^{3a}, and R^{3b} may be bonded to form a ring. X² may be represented by any one of Chemical Formulas D to F.

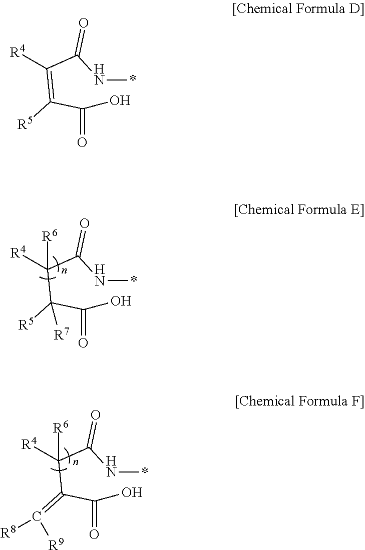

In Chemical Formulas D to F,
R⁴ to R⁹ may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴ to R⁹ may each independently be present or any two adjacent R⁴ to R⁹ may be bonded to form a ring,
n may be an integer of 1 to 5, and
* may be a linking point with Chemical Formula 1-2.

X² may be represented by any one of Chemical Formulas E-1 to E-5.

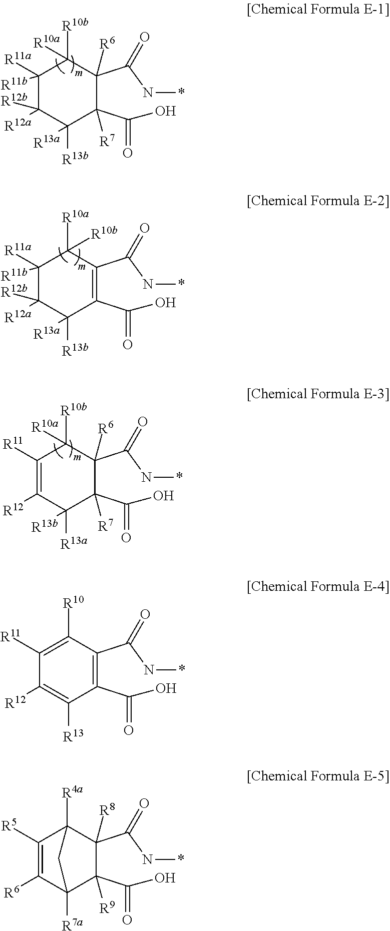

In Chemical Formulas E-1 to E-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be present or any two adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may be bonded to form a ring,
m may be an integer of 0 to 5, and
* may be a linking point with Chemical Formula 1-2.

The first histidine derivative may be represented by Chemical Formula 1-1 and the polishing slurry may further include a second histidine derivative represented by Chemical Formula 1-2.

The abrasive may include an oxide abrasive, a nitride abrasive, a carbon abrasive, or a combination thereof.

The abrasive may include silica, ceria, alumina, zirconia, titania, or a combination thereof.

The polishing slurry may further include a dispersion medium, and the abrasive may be included in an amount of about 0.001 wt % to about 20 wt % based on the polishing slurry.

The oxidizing agent may include hydrogen peroxide, peracetic acid, percarbonate, urea peroxide, perchloric acid, persulfate, or a combination thereof.

The oxidizing agent and the first histidine derivative may be included in the polishing slurry in a molar ratio of about 0.01:10 to about 10:0.01.

The polishing slurry may further include a dispersion medium, and the oxidizing agent and the first histidine derivative may each be included in an amount of about 0.001 wt % to about 5 wt % based on the polishing slurry.

A pH of the polishing slurry may be about 1.0 to about 10.0.

The polishing slurry may further include a chelating agent, a surfactant, a dispersant, a pH regulator, a dispersion medium, or a combination thereof.

According to another embodiment, a method of manufacturing a semiconductor device includes forming a conductive layer on an insulating layer having an opening, supplying a polishing slurry on the conductive layer, and performing chemical mechanical polishing on the conductive layer to form an embedded conductive pattern in the opening of the insulating layer, wherein the polishing slurry includes an abrasive, an oxidizing agent, and the first histidine derivative including a substituted or unsubstituted cyclic imide group.

The first histidine derivative may be represented by Chemical Formula 1-1.

In Chemical Formula 1-1, X¹ may be represented by any one of Chemical Formulas A to C.

In Chemical Formula 1-1, X¹ may be represented by any one of Chemical Formulas B-1 to B-5.

The polishing slurry may further include a second histidine derivative including a substituted or unsubstituted amic acid group.

The second histidine derivative may be represented by Chemical Formula 1-2.

In Chemical Formula 1-2, X² may be represented by any one of Chemical Formulas D to F.

In Chemical Formula 1-2, X² may be represented by any one of Chemical Formulas E-1 to E-5.

The conductive layer may include molybdenum-containing layer.

A removal rate of the molybdenum-containing layer may be greater than or equal to about 110 Å/min, and a static etching rate of the molybdenum-containing layer may be less than about 80 Å/min.

A ratio of the removal rate to the static etching rate of the molybdenum-containing layer may be greater than or equal to about 3.

According to another embodiment, a compound represented by Chemical Formula 1-1 is provided.

According to another embodiment, a compound represented by Chemical Formula 1-2 is provided.

The portions of the object to be polished may be removed at a high polishing rate while effectively reducing or preventing loss or defects of the object to be polished caused by excessive corrosion or over-etching.

### BRIEF DESCRIPTION OF THE DRAWINGS

FIGS. 1, 2, 3, and 4 are cross-sectional views showing an example of a method of manufacturing a semiconductor device according to an embodiment,

FIG. 5 is a schematic view showing a chemical mechanical polishing equipment according to an embodiment,

FIG. 6 is a bar graph showing the polishing rates (RR (removal rate), Angstrom per minute (A/min)) and etching rates (SER (static etching rate) (A/min) for the molybdenum layer of the polishing slurry according to Preparation Examples and Comparative Preparation Examples, and

FIG. 7 is a bar graph showing ratios of the polishing rates and the etching rates (R/SER) for the molybdenum layer of the polishing slurry according to Preparation Examples and Comparative Preparation Examples.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, when a definition is not otherwise provided, ‘substituted’ refers to replacement of hydrogen of a compound or a group by a substituent such as a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, a C7 to C30 arylalkyl group (e.g., benzyl), a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

As used herein, when a definition is not otherwise provided, ‘hetero’ means including 1 to 4 heteroatoms selected from N, O, S, Se, Te, Si, and P.

Hereinafter, the term ‘combination’ includes a mixture and a stacked structure of two or more.

It will be further understood that the terms “comprise” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. All ranges recited herein are inclusive of the endpoints.

Hereinafter, a polishing slurry according to an embodiment is described.

Polishing slurry may be used to planarize a solid surface, such as the surface of a semiconductor substrate (including a thin film or a layer such as an insulating layer or a metal layer), or to remove steps on a solid surface in the manufacturing process of a semiconductor device.

A polishing slurry according to an embodiment includes an abrasive, an oxidizing agent, and an additive.

The abrasive may be an abrasive particle capable of removing all or a portion of an object to be polished, and may be applied to a solid surface covered with the object to be polished to chemically and/or physically remove the object to be polished.

The abrasive may have a predetermined hardness that enables it to remove the object to be polished, and may have, for example, a hardness higher than that of the object to be polished (e.g., a metal or a semi-metal) or an oxide thereof (e.g., a metal oxide or a semi-metal oxide).

The abrasive may be, for example, spherical, plate-shaped, linear, and/or irregularly shaped particles, and the particle size (average particle size, major axis, or length) of the abrasive may be, for example, in the range of about 1 nm to about 150 nm. The abrasive may include a fine abrasive, for example, of greater than or equal to about 1 nm and less than about 50 nm.

The abrasive may include, for example, an oxide abrasive, a nitride abrasive, a carbon abrasive, or a combination thereof, and may be silica, ceria, alumina, zirconia, titania, silicon nitride, SiC, diamond, fullerene, derivatives thereof or a combination thereof, but is not limited thereto.

The abrasive may be included in an amount of less than or equal to about 20 wt % based on the polishing slurry, for example, about 0.001 wt % to about 20 wt %, about 0.001 wt % to about 15 wt %, about 0.001 wt % to about 10 wt %, about 0.001 wt % to about 8 wt %, about 0.001 wt % to about 5 wt %, about 0.001 wt % to about 3 wt %, about 0.01 wt % to about 2 wt %, about 0.1 wt % to about 1.5 wt %, about 0.2 wt % to about 1 wt %, or about 0.3 wt % to about 0.7 wt % based on the polishing slurry.

The oxidizing agent may oxidize the object to be polished, and for example, when applying the polishing slurry to the object to be polished including a metal or a semi-metal, the surface of the object to be polished may be oxidized to form a metal oxide or a semi-metal oxide. The object to be polished oxidized by the oxidizing agent (e.g., the metal oxide or semi-metal oxide) may have a relatively lower hardness and/or may be more brittle than the metal or semi-metal, and may be effectively removed by the abrasive due to the difference in mechanical strength between the object to be polished and the oxidized object to be polished.

The oxidizing agent is not limited as long as it is capable of oxidizing the object to be polished, and may include, for example, hydrogen peroxide, peracetic acid, percarbonates, urea peroxide, perchloride acid, persulfates, or a combination thereof.

The oxidizing agent may be included in an amount of less than or equal to about 5 wt %, and within the above range, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.01 wt % to about 0.3 wt %, about 0.02 wt % to about 0.1 wt %, or about 0.03 wt % to about 0.05 wt % based on the total weight of the polishing slurry.

The additive may include one or more types of histidine derivatives. The histidine derivatives may act as a corrosion inhibitor and may effectively prevent or reduce corrosion and/or over-etching of the object to be polished or its oxide (namely, the oxidized object to be polished) during or after a polishing process.

The histidine derivative may include a histidine derivative including a substituted or unsubstituted cyclic imide group (hereinafter referred to as a ‘first histidine derivative’) instead of an amino group in a substituted or unsubstituted histidine. The cyclic imide group may have a ring structure including two carbonyl groups bonded to nitrogen.

The first histidine derivative may be represented by Chemical Formula 1-1.

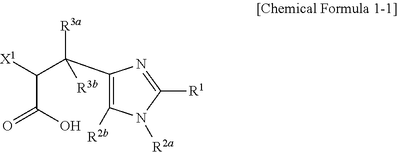

In Chemical Formula 1-1,
X¹ may be a substituted or unsubstituted cyclic imide group,
R¹, R^{2a}, R^{2b}, R^{3a}, and R^{3b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group, and
R¹, R^{2a}, R^{2b}, R^{3a}, and R^{3b} may each independently present or any two adjacent R¹, R^{2a}, R^{2b}, R^{3a}, and R^{3b} may be bonded to form a ring.

The first histidine derivative represented by Chemical Formula 1-1 may be obtained by reacting a histidine including a substituted or unsubstituted imidazolyl group and an amino group with a cyclic acid anhydride, and the substituted or unsubstituted cyclic imide group (X¹) of Chemical Formula 1-1 may be determined depending on the type of the cyclic acid anhydride. However, it is not limited thereto, and the first histidine derivative may be obtained by various methods.

For example, in Chemical Formula 1-1, R¹, R^{2a}, R^{2b}, R^{3a}, and R^{3b} may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, halogen-substituted C2 to C20 alkynyl group, a substituted or unsubstituted phenyl group, a substituted or unsubstituted biphenyl group, a substituted or unsubstituted naphthyl group, a carboxyl group, a hydroxyl group, a cyano group, a halogen (F, Cl, Br, or I), or a combination thereof.

For example, in Chemical Formula 1-1, R¹, R^{2a}, R^{2b}, R^{3a}, and R^{3b} may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formula 1-1, R¹, R^{2a}, R^{2b}, R^{3a}, and R^{3b} may each independently be hydrogen.

For example, in Chemical Formula 1-1, X¹ may be represented by any one of Chemical Formulas A to C.

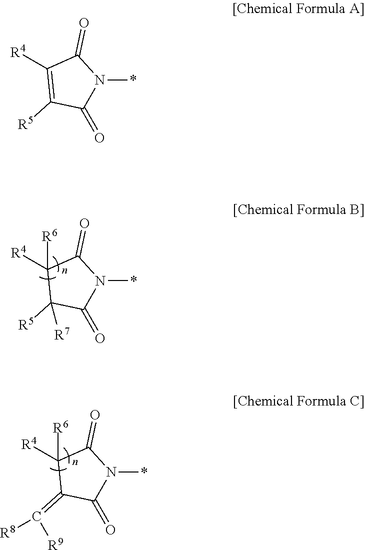

In Chemical Formulas A to C,
R⁴ to R⁹ may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R⁴ to R⁹ may each independently present or any two adjacent R⁴ to R⁹ may be bonded to form a ring,
n may be an integer of 1 to 5, and
* may be a linking point with Chemical Formula 1-1.

For example, in Chemical Formulas A to C, R⁴ to R⁹ may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, in Chemical Formulas A to C, R⁴ to R⁹ may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formula A, R⁴ and R⁵ may each be hydrogen.

For example, in Chemical Formula A, one of R⁴ and R⁵ may be hydrogen and the other of R⁴ and R⁵ may be a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, in Chemical Formula A, R⁴ and R⁵ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula B, R⁴ to R⁷ may each be hydrogen.

For example, in Chemical Formula B, R⁴ to R⁶ may each be hydrogen and R⁷ may be a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, in Chemical Formula B, two of R⁴ to R⁷ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula B, n may be 1, 2, or 3.

For example, in Chemical Formula C, R⁴, R⁶, R⁸, and R⁹ may each be hydrogen.

For example, in Chemical Formula C, two of R⁴, R⁶, R⁸, and R⁹ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula C, n may be 1, 2, or 3.

For example, in Chemical Formula 1-1, X¹ may be represented by any one of Chemical Formulas B-1 to B-5.

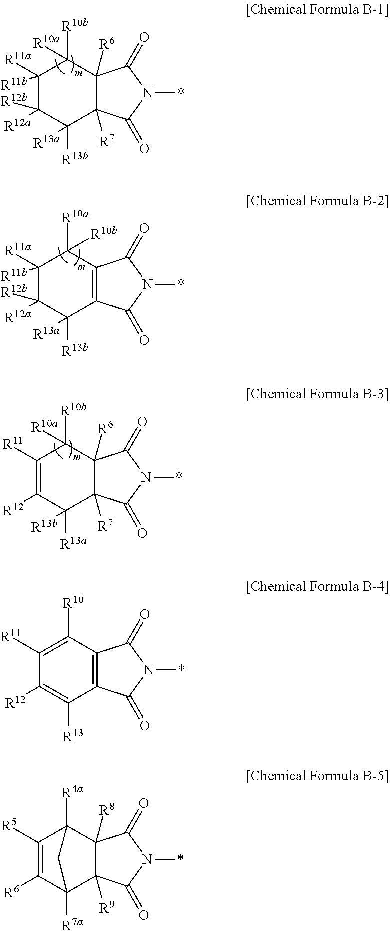

In Chemical Formulas B-1 to B-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently present or any two adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may be bonded to form a ring,
m may be an integer of 0 to 5, and
* may be a linking point with Chemical Formula 1-1.

For example, in Chemical Formulas B-1 to B-5, R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, in Chemical Formulas B-1 to B-5, R^{4a}, R⁵, R⁶, R⁷, R^{7a}, R⁸, R⁹, R¹⁰, R^{10a}, R^{10b}, R¹¹, R^{11a}, R¹¹ b R¹², R^{12a}, R^{12b}, R¹³, R^{13a}, and R^{13b} may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formulas B-1 to B-5, m may be 0, 1, 2, or 3.

For example, in Chemical Formulas B-1 to B-5, R^{4a}, R⁵, R⁶, R⁷, R^{7a}, R⁸, R⁹, R¹⁰, R^{10a}, R^{10b}, R¹¹, R^{11a}, R¹¹ b R¹², R^{12a}, R^{12b}, R¹³, R^{13a}, and R^{13b} may each independently be hydrogen.

For example, in Chemical Formulas B-1 to B-3, R^{10a} and R^{13a} may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formulas B-1 to B-3, R^{11a} and R^{13a} may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula B-4, any two of R¹⁰ to R¹³ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula B-4, any one of R¹⁰ to R¹³ may be a carboxyl group.

The histidine derivative may further include a histidine derivative including a substituted or unsubstituted amic acid group (hereinafter referred to as a ‘second histidine derivative’) instead of an amino group in a substituted or unsubstituted histidine. The amic acid group may have a non-cyclic structure including one or more amide groups and one or more carboxylic acid groups.

The second histidine derivative may be represented by Chemical Formula 1-2.

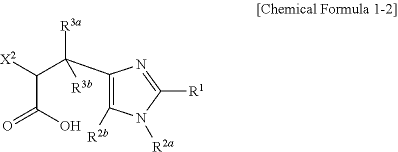

In Chemical Formula 1-2,
X² may be a substituted or unsubstituted amic acid group, R¹, R^{2a}, R^{2b}, R^{3a}, and R^{3b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group, and
R¹, R^{2a}, R^{2b}, R^{3a}, and R^{3b} may each independently be present or any two adjacent groups of R¹, R^{2a}, R^{2b}, R^{3a}, and R^{3b} may be bonded to form a ring.

The second histidine derivative represented by Chemical Formula 1-2 may be obtained, for example, by a ring opening reaction when histidine including a substituted or unsubstituted imidazolyl group and an amino group is reacted with a cyclic acid anhydride, and the substituted or unsubstituted amic acid group (X²) of Chemical Formula 1-2 may be determined depending on the type of the cyclic acid anhydride. However, it is not limited thereto, and the second histidine derivative may be obtained by various methods.

For example, in Chemical Formula 1-2, R¹, R^{2a}, R^{2b}, R^{3a}, and R^{3b} may each independently be hydrogen, deuterium, a C1 to C20 alkyl group, a halogen-substituted C1 to C20 alkyl group, a C2 to C20 alkenyl group, a halogen-substituted C2 to C20 alkenyl group, C2 to C20 alkynyl group, halogen-substituted C2 to C20 alkynyl group, a substituted or unsubstituted phenyl group, a substituted or unsubstituted biphenyl group, a substituted or unsubstituted naphthyl group, a carboxyl group, a hydroxyl group, a cyano group, a halogen (F, Cl, Br, or I), or a combination thereof.

For example, in Chemical Formula 1-2, R¹, R^{2a}, R^{2b}, R^{3a}, and R^{3b} may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formula 1-2, R¹, R^{2a}, R^{2b}, R^{3a}, and R^{3b} may each independently be hydrogen.

For example, in Chemical Formula 1-2, X¹ may be represented by any one of Chemical Formulas D to F.

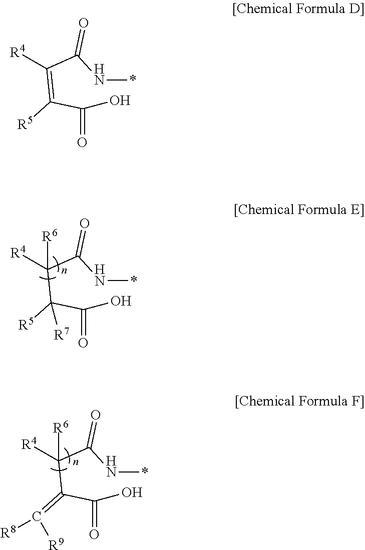

In Chemical Formulas D to F,
R⁴ to R⁹ may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R⁴ to R⁹ may each independently be present or any two adjacent R⁴ to R⁹ may be bonded to form a ring,
n may be an integer of 1 to 5, and
* may be a linking point with Chemical Formula 1-2.

For example, in Chemical Formulas D to F, R⁴ to R⁹ may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, in Chemical Formulas D to F, R⁴ to R⁹ may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formula D, R⁴ and R⁵ may each be hydrogen.

For example, in Chemical Formula D, one of R⁴ and R⁵ may be hydrogen and the other of R⁴ and R⁵ may be a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxyl group, a cyano group, a halogen (F, Cl, Br, or I), or a combination thereof.

For example, in Chemical Formula D, R⁴ and R⁵ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula E, R⁴ to R⁷ may each be hydrogen.

For example, in Chemical Formula E, R⁴ to R⁶ may each be hydrogen and R⁷ may be a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxyl group, a cyano group, a halogen (F, Cl, Br, or I), or a combination thereof.

For example, in Chemical Formula E, two of R⁴ to R⁷ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula E, n may be 1, 2, or 3.

For example, in Chemical Formula F, R⁴, R⁶, R⁸, and R⁹ may each be hydrogen.

For example, in Chemical Formula F, two of R⁴, R⁶, R⁸, and R⁹ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula F, n may be 1, 2, or 3.

For example, in Chemical Formula 1-2, X² may be represented by any one of Chemical Formulas E-1 to E-5.

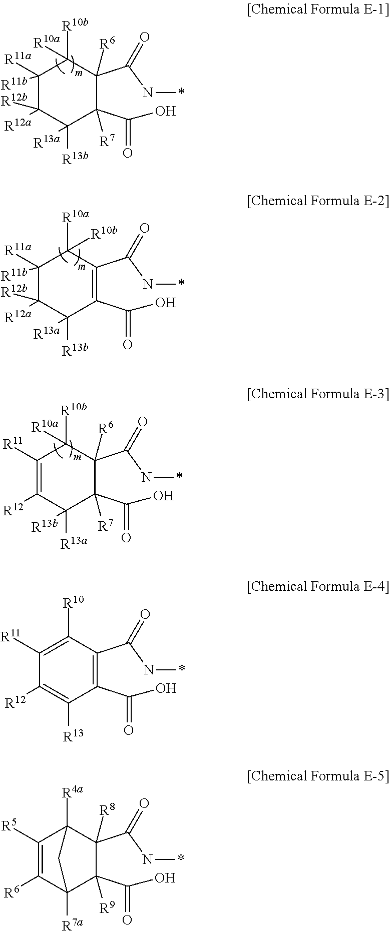

In Chemical Formulas E-1 to E-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxyl group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may each independently be present or any two of adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} may be bonded to form a ring,
m may be an integer of 0 to 5, and
* may be a linking point with Chemical Formula 1-2.

For example, in Chemical Formulas E-1 to E-5, R^{4a}, R⁵, R⁶, R⁷, R^{7a}, R⁸, R⁹, R¹⁰, R^{10a}, R^{10b}, R¹¹, R^{11a}, R¹¹ b R¹², R^{12a}, R^{12b}, R¹³, R^{13a}, and R^{13b} may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxyl group, a cyano group, a halogen (F, Cl, Br, or I), or a combination thereof.

For example, in Chemical Formulas E-1 to E-5, R^{4a}, R⁵, R⁶, R⁷, R^{7a}, R⁸, R⁹, R¹⁰, R^{10a}, R^{10b}, R¹¹, R^{11a}, R¹¹ b R¹², R^{12a}, R^{12b}, R¹³, R^{13a}, and R^{13b} may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a phenyl group, a biphenyl group, a naphthyl group, a halogen-substituted phenyl group, a halogen-substituted biphenyl group, a halogen-substituted naphthyl group, a carboxyl group, a halogen (F, Cl, Br, or I), or a combination thereof.

For example, in Chemical Formulas E-1 to E-5, m may be 0, 1, 2, or 3.

For example, in Chemical Formulas E-1 to E-5, R^{4a}, R⁵, R⁶, R⁷, R^{7a}, R⁸, R⁹, R¹⁰, R^{10a}, R^{10b}, R¹¹, R^{11a}, R¹¹ b R¹², R^{12a}, R^{12b}, R¹³, R^{13a}, and R^{13b} may each independently be hydrogen.

For example, in Chemical Formulas E-1 to E-3, R^{10a} and R^{13a} may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formulas E-1 to E-3, R^{11a} and R^{13a} may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula E-4, any two of R¹⁰ to R¹³ may be bonded to form a ring. Herein, the ring may include a substituted or unsubstituted C3 to C20 aliphatic ring, a substituted or unsubstituted C6 to C20 aromatic ring, or a combination thereof.

For example, in Chemical Formula E-4, any one of R¹⁰ to R¹³ may be a carboxyl group.

The histidine derivative may include the first histidine derivative, the second histidine derivative, or a combination thereof. For example, the histidine derivative may include the first histidine derivative and the second histidine derivative.

The histidine derivative (for example, the first histidine derivative) may be included in an amount of less than or equal to about 5 wt % based on the polishing slurry, and within the above range, may be included in an amount of about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.01 wt % to about 0.3 wt %, about 0.01 wt % to about 0.1 wt %, or about 0.02 wt % to about 0.04 wt % based on the polishing slurry.

The histidine derivative (for example, the first histidine derivative) may be included at a concentration of less than or equal to about 0.1 mol/L based on the polishing slurry, and within the above range, may be included at a concentration of about 0.001 to about 0.1 mol/L, about 0.001 to about 0.08 mol/L, about 0.001 to about 0.06 mol/L, about 0.001 to about 0.05 mol/L, about 0.005 to about 0.03 mol/L, about 0.007 to about 0.02 mol/L, or about 0.008 to about 0.015 mol/L based on the polishing slurry.

The oxidizing agent and the histidine derivative may be included in an appropriate molar ratio to increase the polishing rate and reduce corrosion or over-etching, for example, in a molar ratio of about 0.01:10 to about 10:0.01, and within the above range, the oxidizing agent and the histidine derivative may be included in a molar ratio of about 0.1:10 to about 10:0.1, about 1:10 to about 10:1, about 2:8 to about 8:2, about 3:7 to about 7:3, about 4:6 to about 6:4 or about 5:5.

Other additives that may optionally be used may further include a chelating agent, a surfactant, a dispersant, a pH regulator, a reaction catalyst, or a combination thereof.

The chelating agent may be phosphoric acid, nitric acid, citric acid, malonic acid, a salt thereof, or a combination thereof, but is not limited thereto.

The surfactant may be an ionic or nonionic surfactant, and may be, for example a copolymer of ethylene oxide, a copolymer of propylene oxide, an amine compound, or a combination thereof, but is not limited thereto.

The dispersant may facilitate dispersion of the abrasive and may include, for example, a water-soluble monomer, a water-soluble oligomer, a water-soluble polymer, a metal salt, or a combination thereof. A weight average molecular weight of the water-soluble polymer may be, for example, less than or equal to about 10,000 grams per mole (g/mol), for example, less than or equal to about 5000 g/mol, for example, less than or equal to about 3000 g/mol. The metal salt may be, for example, a copper salt, a nickel salt, a cobalt salt, a manganese salt, a tantalum salt, a ruthenium salt, or a combination thereof. The dispersant may be poly(meth)acrylic acid, poly(meth)acrylic maleic acid, polyacrylonitrile-co-butadiene-acrylic acid, carboxylic acids, sulfonic esters, sulfonic acid, phosphoric ester, cellulose, diol, a salt thereof, or a combination thereof, but is not limited thereto.

The pH regulator may adjust the pH of the polishing slurry and may be, for example, an inorganic acid, an organic acid, a salt thereof, or a combination thereof. The inorganic acid may include nitric acid, hydrochloric acid, phosphoric acid, sulfuric acid, hydrofluoric acid, hydrobromic acid, iodic acid, or a salt thereof, and organic acids may include, but are not limited to, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto. A base may be used to adjust the pH of the polishing slurry, for example an inorganic base such as potassium hydroxide or sodium hydroxide, but is not limited thereto.

The reaction catalyst may promote an oxidation reaction of the object to be polished by catalyzing decomposition of the oxidizing agent. The reaction catalyst may be, for example, a metal ion compound capable of effectively generating radicals, and may be, for example, a catalyst used in a Fenton reaction or a Fenton-like reaction. The reaction catalyst may include, for example, a cation including an iron (Fe) ion, a chromium (Cr) ion, a manganese (Mn) ion, a cobalt (Co) ion, a cerium (Ce) ion, a potassium (K) ion, a silver (Ag) ion, a copper (Cu) ion, a molybdenum (Mo) ion, a niobium (Nb) ion, a nickel (Ni) ion, an osmium (Os) ion, a lead (Pb) ion, a tin (Sn) ion, a titanium (Ti) ion, a vanadium (V) ion, or a combination thereof, and an anion including a nitrate, a sulfate, a fluoride, a chloride, a bromide, an iodide, a fluorate, a chlorate, a bromate, an iodate, a perchlorate, a perbromate, a periodate, a cyanide salt, an oxalate, a citrate, an acetate, an acetylacetonate, a gluconate, or a combination thereof, but is not limited thereto. For example, the reaction catalyst may be an iron ion catalyst, such as iron nitrate (II), iron nitrate (III), iron sulfate (II), iron sulfate (III), iron oxalate (II), iron oxalate (III), or a combination thereof, but is not limited thereto.

Each component of the additive (other than the first histidine derivative the second histidine derivative, or a combination thereof) may each independently be included in trace amounts, for example, from about 1 ppm to about 100,000 ppm, but is not limited thereto.

The polishing slurry may further include a dispersion medium or solvent (hereinafter referred to as ‘dispersion medium’) capable of dispersing and/or dissolving the above-described components, and the dispersion medium may be, for example, water. The water may be, for example, distilled water and/or deionized water.

The dispersion medium may be included as a balance amount excluding solids such as abrasives, oxidizing agents, and additives.

The pH of the polishing slurry may be about 1.0 to about 10.0, and within the above range may be about 1.0 to about 7.0 or about 1.0 to about 5.0.

The polishing slurry may be used in the formation of various structures, for example, it may be used in the polishing process of a conductive material such as a metal layer, or an insulating material such as a shallow trench isolation (STI) or an insulating layer. For example, the polishing slurry may be used to polish a conductive material such as a metal wire, a via, and/or an electrode in a semiconductor substrate, and may be used to polish a conductive material such as tungsten, molybdenum, aluminum, copper, nickel, or alloys thereof, and may be used to polish a molybdenum (Mo) containing layer or a molybdenum alloy.

An example of a method of manufacturing a semiconductor device according to an embodiment using the polishing slurry is described below.

A method of manufacturing a semiconductor device according to an embodiment includes performing chemical mechanical polishing (CMP) on all or a portion of a surface of an object to be polished. The object to be polished may be a variety of structures, for example, a semiconductor substrate such as a silicon wafer (including a thin film or a layer such as an insulating layer or a metal layer), and the polishing surface may include a metal such as molybdenum, aluminum, copper or nickel, an alloy thereof, or a metal oxide or semi-metal oxide generated during a chemical-mechanical polishing process; an oxide such as silicon oxide or molybdenum oxide; a nitride such as silicon nitride, aluminum nitride, titanium nitride or gallium nitride; a carbide such as silicon carbide; a semiconductor such as silicon or germanium; a compound semiconductor such as InP, GaAs; an organic or inorganic compound such as tetraethylorthosilicate (TEOS); or a combination thereof.

For example, the polishing slurry may be used to polish a conductive material such as a metal layer in a semiconductor substrate, and may be used to form a metal wire, a via, and/or an electrode from a conductive layer including, for example, molybdenum (Mo) or a Mo alloy.

Hereinafter, an example of a method of manufacturing a semiconductor device using the aforementioned polishing slurry is described.

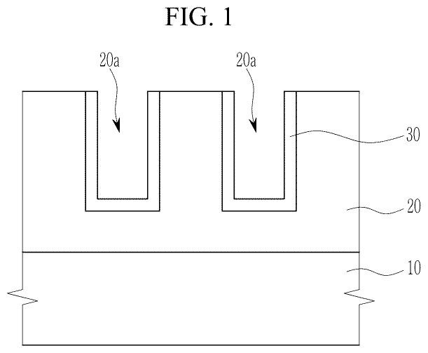

FIGS. 1 to 4 are cross-sectional views showing an example of a method of manufacturing a semiconductor device according to an embodiment.

Referring to FIG. 1, an insulating layer 20 is formed on a semiconductor substrate 10. The insulating layer 20 may include an oxide, nitride and/or oxynitride. The insulating layer 20 may be a dielectric layer. Next, the insulating layer 20 is etched to form an opening 20a. The opening 20a may include a trench, a via hole, and/or a contact hole. For example, the opening 20a may have a width of less than about 10 nanometers (nm), for example 0.1 to 10 nm, but is not limited thereto. Next, a barrier layer 30 is formed on the inside wall of the opening 20a. The barrier layer 30 may include, for example, Ta and/or TaN, but is not limited thereto.

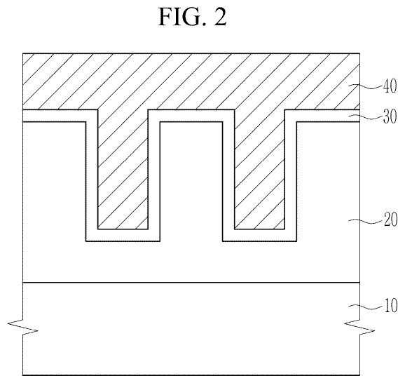

Referring to FIG. 2, the inside and top of the opening 20a are filled or coated with a metal to form a conductive layer 40. The conductive layer 40 may include, for example, a metal such as tungsten, molybdenum, aluminum, copper or nickel, an alloy thereof, or a combination thereof, and may include, for example, molybdenum (Mo) or a Mo alloy. For example, when the barrier layer 30 is a Ta layer and the conductive layer 40 is a Mo-containing layer, the higher the polishing selectivity of Ta to Mo in the polishing slurry, the more desirable, and for example, the higher it is than about 50:1, the more desirable.

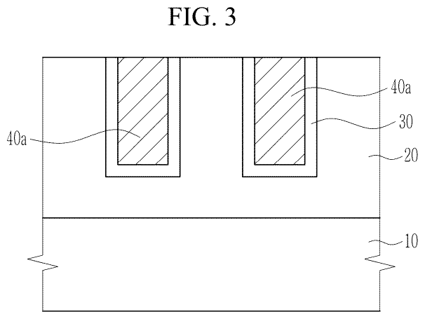

Referring to FIG. 3, the surface of the conductive layer 40 may be planarized to substantially match the surface of the insulating layer 20 to form an embedded conductive pattern 40a. The planarization may be performed by chemical mechanical polishing (CMP) using CMP equipment, and the polishing slurry described above may be used. CMP equipment will be described below.

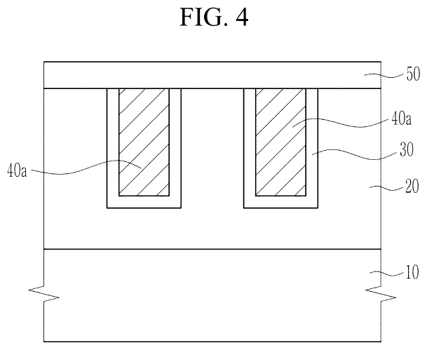

Referring to FIG. 4, a capping layer 50 is formed on the embedded conductive pattern 40a and the insulating layer 20. The capping layer 50 may include SiN and/or SiC, but is not limited thereto.

Hereinafter, the planarization for forming the embedded conductive pattern 40a is described. The planarization may be performed by CMP using a CMP equipment as described above.

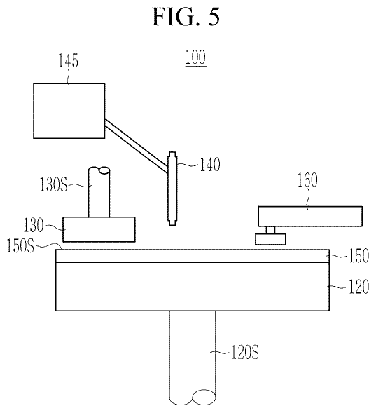

FIG. 5 is a schematic view showing a CMP equipment according to an example.

Referring to FIG. 5, a CMP equipment 100 according to an example may include, for example, a lower base (not shown); a platen 120 rotatably provided on an upper surface of the lower base; a polishing head 130; a polishing pad 150 on the platen 120; a pad conditioner 160; and at least one polishing slurry supply device 140 disposed adjacent to the polishing pad 150 to supply polishing slurry to the polishing pad 150.

The platen 120 may be provided rotatable on the surface of the lower base. For example, the platen 120 may receive rotational power from a motor (not shown) disposed in the lower base, and accordingly may rotate in a certain direction, such as clockwise or counterclockwise, by a rotation axis 120S perpendicular to the surface of the platen 120.

The polishing head 130 may be disposed on the platen 120 and may hold a body to be polished. The body to be polished may be a semiconductor substrate 10, such as a wafer. The polishing head 130 may include a rotating shaft 130S that rotates the body to be polished. When performing polishing, the rotation direction of the polishing head 130 may be opposite to the rotation direction of the platen 120.

The polishing pad 150 may be disposed on the platen 120 so as to be supported by the platen 120. The polishing pad 150 may rotate together with the platen 120. The polishing pad 150 may have a roughly formed polishing surface 150S. This polishing surface 150S may mechanically polish the surface of the semiconductor substrate 10 by directly contacting the semiconductor substrate 10. The polishing pad 150 may be made of a porous material with a plurality of microspaces, and the plurality of microspaces may accommodate polishing slurry. The polishing surface 150S of the polishing pad 150 may include a surface that directly contacts the body to be polished and a predetermined depth therefrom, and the predetermined depth may be about 10% to about 100%, about 20% to about 100%, about 30% to about 100%, about 40% to about 100%, or about 50% to about 100% of the thickness of the polishing pad 150. The polishing surface 150S of the polishing pad 150 may be flat, for example. The polishing surface 150S of the polishing pad 150 may have, for example, protrusions or grooves.

A pad conditioner 160 may be adjacent to the polishing pad 150 and may maintain the state of the polishing surface so that the surface of the semiconductor substrate 10 may be effectively polished while the polishing process is performed.

The polishing slurry supply device 140 may be adjacent to the polishing pad 150 and may supply polishing slurry from the polishing slurry tank 145 and supply the polishing slurry to the polishing pad 150. The polishing slurry supply device 140 may include a nozzle capable of supplying polishing slurry onto the polishing pad 150 during the polishing process. The polishing slurry supply device 140 may supply the polishing slurry.

CMP may be performed, for example, by disposing a semiconductor substrate 10 and a polishing pad 150 so as to face each other, supplying the polishing slurry between the semiconductor substrate 10 and the polishing pad 150 from a polishing slurry supply device 140, and performing polishing by contacting the polishing pad 150 with the surface of the semiconductor substrate 10.

For example, the supplying of the polishing slurry may be supplied at a rate of, for example, about 10 milliliters per minute (ml/min) to about 300 ml/min.

The performing of polishing may be performed by mechanical friction by contacting the polishing pad 150 with the surface of the semiconductor substrate 10 and rotating it. For example, a pressure of about 1 pound per square inch (psi) to about 5 psi may be applied during the polishing.

For example, the oxidizing agent of the polishing slurry may oxidize a surface of the object to be polished (e.g., a metal such as molybdenum) to form a metal oxide (e.g., molybdenum oxide) at a predetermined thickness in the object to be polished, and in the performing of polishing, the abrasive may perform polishing by physically and/or chemically removing the metal oxide on the polishing surface. The histidine derivative of the polishing slurry may effectively prevent or reduce defects caused by excessive corrosion or over-etching of the surface of the object to be polished (e.g., a metal such as molybdenum) during the polishing as a corrosion inhibitor. Oxidation and prevention of corrosion or over-etching of the polishing surface may be performed simultaneously or sequentially.

In this way, the polishing slurry may increase the polishing rate of the object to be polished, while effectively reducing or preventing loss or defects caused by excessive corrosion or over-etching by including the abrasive, the oxidizing agent, and the histidine derivative.

For example, the conductive layer 40 may include Mo-containing layer, and the removal rate (RR) of the Mo-containing layer may be greater than or equal to about 110 Å/min, and within the above range, about 110 Å/min to about 1000 Å/min, about 120 Å/min to about 1000 Å/min, about 130 Å/min to about 1000 Å/min, about 130 Å/min to about 500 Å/min, about 135 Å/min to about 300 Å/min, about 140 Å/min to about 200 Å/min, or about 140 Å/min to about 150 Å/min, and the etching rate (static etching rate, SER) of the Mo-containing layer may be less than about 80 Å/min, and within the above range, greater than or equal to about 1 Å/min and less than about 80 Å/min, about 3 Å/min to about 70 Å/min, about 5 Å/min to about 60 Å/min, about 5 Å/min to about 40 Å/min, about 6 Å/min to about 20 Å/min, about 7 Å/min to about 15 Å/min, or about 7.5 Å/min to about 12 Å/min. For example, a ratio of the polishing rate to the static etching rate of the Mo-containing layer may be greater than or equal to about 3, and within the above range, about 3 to about 80, about 5 to about 80, about 7 to about 80, about 9 to about 80, about 10 to about 80, about 12 to about 80, about 12 to about 50, about 12 to about 40, or about 12 to about 20.

Although a method of manufacturing a semiconductor device according to an example is described above, it is not limited thereto, and may be applied to semiconductor devices with various structures.

Hereinafter, the embodiments are illustrated in more detail with reference to examples. However, these examples are exemplary, and the scope of claims is not limited thereto.

### SYNTHESIS EXAMPLES

### Synthesis Example 1

3 g of itaconic anhydride is dissolved in 20 milliliters (mL) of acetic acid in a 250 mL round bottom flask to prepare an itaconic anhydride solution. In another flask, 4.0 g of L-histidine is dissolved in 30 mL of acetic acid and is added drop-wise to the itaconic anhydride solution. The reaction is carried out at room temperature overnight. Then, the product obtained therefrom is precipitated into acetone, and the acetone is decanted to obtain a precipitate. Subsequently, the precipitate is dissolved in water, reprecipitated into the acetone twice, and lyophilized to obtain 5.97 g of histidine derivatives (Compounds 1-1a and 1-2a) in the form of crystalline powder. A yield thereof is 93%.

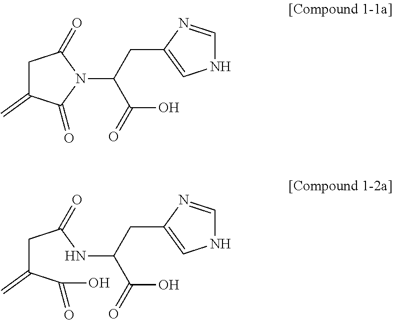 [SMILES: C=C1CC(=O)N(C(Cc2c[nH]cn2)C(=O)O)C1=O ; C=C(CC(=O)NC(Cc1c[nH]cn1)C(=O)O)C(=O)O]

¹H NMR (D₂O), δ (ppm): 3.02 (1H, dd), 3.1-3.3 (1H, dd, 2H, s), 4.46 (1H, t), 5.67 (1H, s), 6.17 (1H, s), 7.14 (1H, s), 8.48 (1H, s).

### Synthesis Example 2

2.557 g of maleic anhydride is dissolved in 40 mL of acetic acid in a 250 mL round bottom flask to prepare a maleic anhydride solution. In another flask, 4.0 g of L-histidine is dissolved in 40 mL of acetic acid and is added drop-wise to the maleic anhydride solution. The reaction is carried out at room temperature overnight. Then, the product obtained therefrom is precipitated in the large amount of acetone, and the acetone is decanted to obtain a precipitate. Subsequently, the precipitate is dissolved in water, reprecipitated into acetone twice and lyophilized to obtain 5.29 g of histidine derivatives (Compounds 1-1b and 1-2b) in the form of crystalline powder. A yield thereof is 81%.

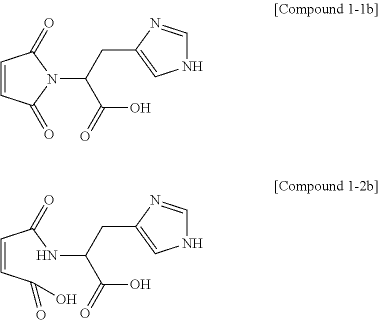 [SMILES: O=C(O)C(Cc1c[nH]cn1)N1C(=O)C=CC1=O ; O=C(O)/C=C\C(=O)NC(Cc1c[nH]cn1)C(=O)O]

¹H NMR (D₂O), δ (ppm): 3.11 (1H, dd), 3.21 (1H, dd), 4.56 (1H, t), 6.28 (2H, s), 7.18 (1H, s), 8.49 (1H, s).

### PREPARATION EXAMPLE

### Preparation Example 1

0.5 wt % of colloidal silica (an average particle diameter: 30 nm), 0.034 wt % (0.01 mole per Liter (mol/L)) of hydrogen peroxide, 0.0249 wt % (0.01 mol/L) of histidine derivatives obtained in Synthesis Example 1, a small amount of nitric acid, and a balance amount of deionized water are mixed to prepare a polishing slurry of pH 2.0.

### Preparation Example 2

A polishing slurry is prepared in the same manner as in Preparation Example 1 except that 0.235 wt % (0.01 mol/L) of histidine derivatives obtained in Synthesis Example 2 is used instead of histidine derivatives obtained in Synthesis Example 1.

### Comparative Preparation Example 1

A polishing slurry is prepared in the same manner as in Preparation Example 1 except that the histidine derivatives obtained in Synthesis Example 1 are not included.

### Comparative Preparation Example 2

A polishing slurry is prepared in the same manner as in Preparation Example 1 except that L-histidine represented by Chemical Formula A is used instead of the histidine derivatives obtained in Synthesis Example 1.

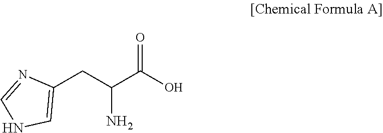 [SMILES: NC(Cc1c[nH]cn1)C(=O)O]

### Evaluation I

The polishing slurries according to Preparation Examples 1 and 2 and Comparative Preparation Examples 1 and 2 are evaluated with respect to a polishing rate (removal rate, RR) of each Mo layer.

CMP is performed under the following conditions.
(1) CMP equipment: GNP POLI-400L (G&P Technology, Inc.)
(2) Body to be polished: 40 mm×40 mm silicon wafer coupon with a 5000 Å-thick Mo layer formed by physical vapor deposition (PVD)
(3) Polishing head rotation speed: 87 rpm
(4) Polishing platen rotation speed: 93 rpm
(5) Applied pressure: 3 psi
(6) Initial temperature: 24° C.
(7) Polishing slurry: Polishing slurry according to Preparation Examples 1 and 2 and Comparative Preparation Examples 1 and 2 (45° C.)
(8) Polishing slurry supply flow rate: 130 ml/min.
(9) Polishing time: 1 minute

The chemical mechanical polishing rate (removal rate, RR) is calculated according to Calculation Equation 1. In Calculation Equation 1, a thickness of the Mo layer is calculated from sheet resistance and volume resistivity, which are measured using a resistance meter (Model “RS-100”, KLA Tencor) in a DC 4-probe method, according to Calculation Equation 2.

$$Removal rate ( RR , Å / min ) = ( thickness of Mo layer before polishing ( Å ) - thickness of Mo layer after polishing ( Å ) ) / polishing time ( min ) \qquad [ Calculation Equation 1 ]$$

$$Mo layer thickness ( Å ) = [ volume resistivity ( Ω \cdot m ) \div sheet resistance ( Ω ) ] \times {10}^{10} \qquad [ Calculation Equation 2 ]$$

### Evaluation II

The polishing slurries according to Preparation Examples 1 and 2 and Comparative Preparation Examples 1 and 2 are evaluated with respect to an etching rate (static etching rate, SER) of each Mo layer. 40 mm×40 mm silicon wafers covered with a 5000 Å-thick Mo layer formed by PVD are immersed in each of the polishing slurries according to Preparation Examples 1 and 2 and Comparative Preparation Examples 1 and 2 for 30 minutes. Subsequently, the silicon wafers are taken out and washed with deionized water. Then, the obtained Mo layers are measured with respect to a thickness before and after the immersion in the same method as above, which is used to calculate the static etching rate (SER, Å/min) according to Calculation Equation 3 below.

$$Static etching rate ( SER , Å / min ) = ( Thickness of Mo layer before immersion ( Å ) - Thickness of Mo layer after immersion ( Å ) ) / Immersion time ( min ) \qquad [ Calculation Equation 3 ]$$

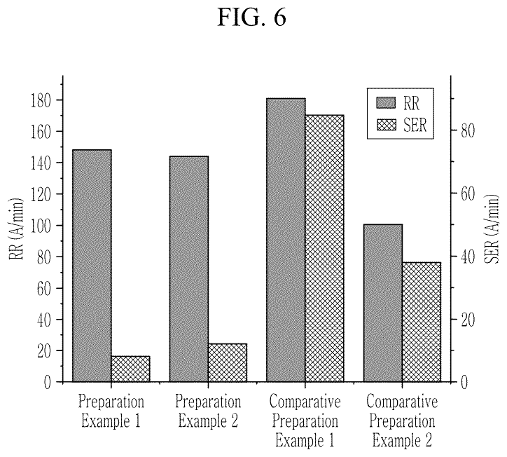

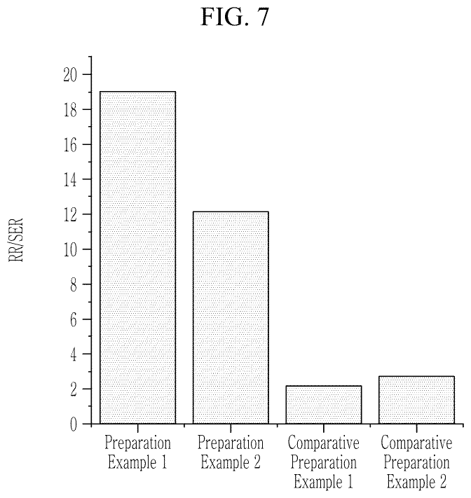

The results are shown in Tables 1 and FIGS. 6 and 7.

FIG. 6 is a bar graph showing the polishing rates and etching rates for the Mo layer of the polishing slurry according to Preparation Examples and Comparative Preparation Examples, and FIG. 7 is a bar graph showing ratios of the polishing rates and the etching rates for the Mo layers of the polishing slurries according to Preparation Examples and Comparative Preparation Examples.

TABLE 1

| | RR | SER | |
|---|---|---|---|
| | (Å/min) | (Å/min) | RR/SER |
| Preparation Example 1 | 148.6 | 7.8 | 19.05 |
| Preparation Example 2 | 144.3 | 11.9 | 12.13 |
| Comparative Preparation Example 1 | 181.2 | 85 | 2.13 |
| Comparative Preparation Example 2 | 100.4 | 38 | 2.64 |

* RR: Removal Rate
* SER: Static Etching Rate

Referring to Table 1 and FIGS. 6 and 7, the polishing slurries according to Preparation Examples 1 and 2 exhibit significantly lower static etching rates than the polishing slurry according to Comparative Preparation Example 1. Accordingly, it may be confirmed that the histidine derivatives (corrosion inhibitor) obtained in Synthesis Examples may effectively reduce corrosion or over-etching of the Mo layer.

In addition, the polishing slurries according to Preparation Examples 1 and 2 may increase a polishing rate (removal rate) while decreasing a static etching rate, compared with the polishing slurry according to Comparative Preparation Example 2. Accordingly, it may be confirmed that the histidine derivatives obtained in Synthesis Examples may effectively increase a polishing rate (removal rate) while decreasing corrosion or over-etching, compared with a histidine.

Accordingly, it may be confirmed that the polishing slurries according to Preparation Examples 1 and 2, compared with the polishing slurries according to Comparative Preparation Examples 1 and 2, may increase a ratio of the polishing rate (removal rate) to the static etching rate of the Mo layer by more than 5 times.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A polishing slurry, comprising:
an abrasive,
an oxidizing agent, and
a first histidine derivative including a substituted or unsubstituted cyclic imide group.

2. The polishing slurry of claim 1, wherein the first histidine derivative is represented by Chemical Formula 1-1: 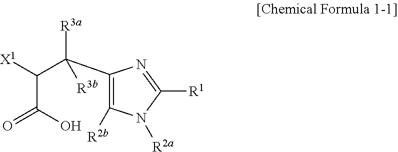
wherein, in Chemical Formula 1-1,
X¹ is a substituted or unsubstituted cyclic imide group,
R¹, R^{2a}, R^{2b}, R^{3a} and R^{3b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or two adjacent two of R¹, R^{2a}, R^{2b}, R^{3a}, and R^{3b} are bonded to form a ring.

3. The polishing slurry of claim 2, wherein X¹ is represented by any one of Chemical Formulas A to C: 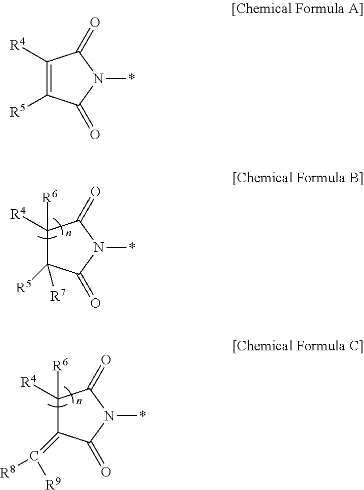
wherein, in Chemical Formulas A to C,
R⁴ to R⁹ are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴ to R⁹ are each independently present or any two adjacent R⁴ to R⁹ are bonded to form a ring,
n is an integer of 1 to 5, and
* is a linking point with Chemical Formula 1-1.

4. The polishing slurry of claim 3, wherein X¹ is represented by any one of Chemical Formulas B-1 to B-5: 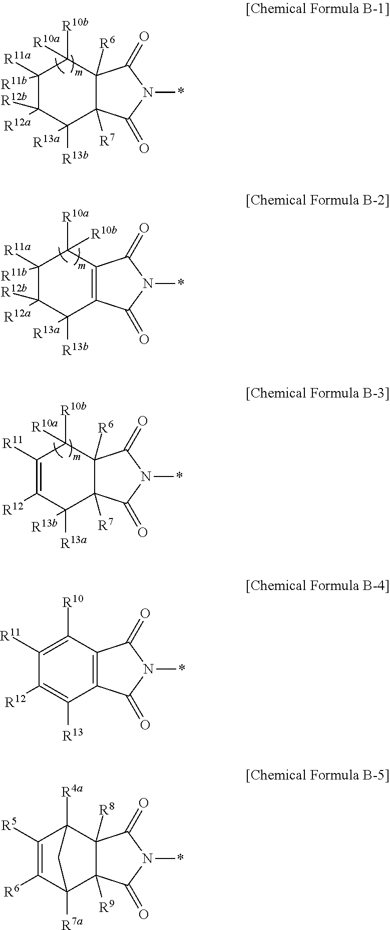
wherein, in Chemical Formulas B-1 to B-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently present or any two adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are bonded to form a ring,
m is an integer of 0 to 5, and
* is a linking point with Chemical Formula 1-1.

5. The polishing slurry of claim 1, further comprising a second histidine derivative including a substituted or unsubstituted amic acid group.

6. The polishing slurry of claim 5, wherein the second histidine derivative is represented by Chemical Formula 1-2: 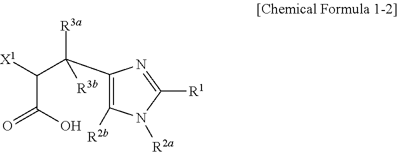
wherein, in Chemical Formula 1-2,
X² is a substituted or unsubstituted amic acid group,
R¹, R^{2a}, R^{2b}, R^{3a}, and R^{3b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent R¹, R^{2a}, R^{2b}, R^{3a}, and R^{3b} are bonded to form a ring.

7. The polishing slurry of claim 6, wherein X² is represented by any one of Chemical Formulas D to F: 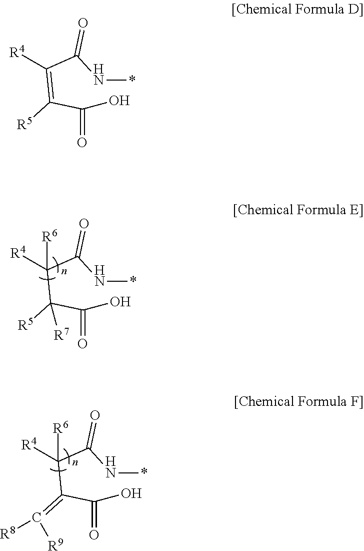
wherein, in Chemical Formulas D to F,
R⁴ to R⁹ are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴ to R⁹ are each independently present or any two of adjacent two of R⁴ to R⁹ are bonded to form a ring,
n is an integer of 1 to 5, and
* is a linking point with Chemical Formula 1-2.

8. The polishing slurry of claim 6, wherein X² is represented by any one of Chemical Formulas E-1 to E-5: 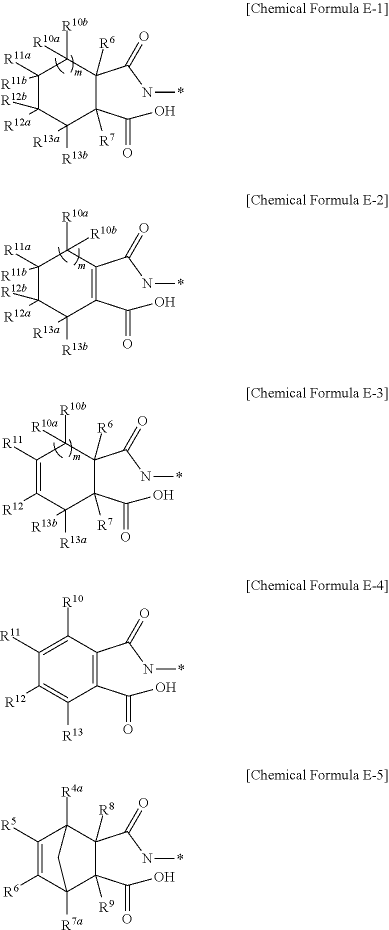
wherein, in Chemical Formulas E-1 to E-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b} R¹³, R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently present or any two of the adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are bonded to form a ring,
m is an integer of 0 to 5, and
* is a linking point with Chemical Formula 1-2.

9. The polishing slurry of claim 1, wherein the first histidine derivative is represented by Chemical Formula 1-1, and
the polishing slurry further includes a second histidine derivative represented by Chemical Formula 1-2: 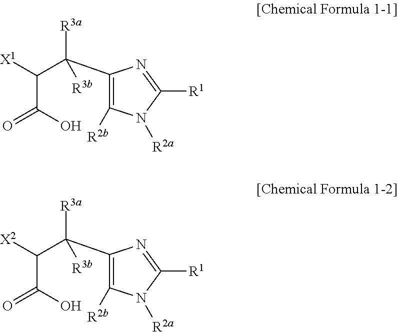
wherein, in Chemical Formulas 1-1 and 1-2,
X¹ is a substituted or unsubstituted cyclic imide group,
X² is a substituted or unsubstituted amic acid group,
R¹, R^{2a}, R^{2b}, R^{3a}, and R^{3b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent R¹, R^{2a}, R^{2b}, R^{3a}, and R^{3b} are bonded to form a ring,

10. The polishing slurry of claim 1, wherein the oxidizing agent and the first histidine derivative are included in the polishing slurry in a molar ratio of about 0.01:10 to about 10:0.01.

11. The polishing slurry of claim 1, further comprising a dispersion medium,
wherein the oxidizing agent and the first histidine derivative are each included in an amount of about 0.001 wt % to about 5 wt % based on the polishing slurry.

12. A method of manufacturing a semiconductor device, the method comprising:
forming a conductive layer on an insulating layer having an opening,
supplying a polishing slurry on the conductive layer, and
performing chemical mechanical polishing on the conductive layer to form an embedded conductive pattern in the opening of the insulating layer,
wherein the polishing slurry comprises an abrasive, an oxidizing agent, and a first histidine derivative including a substituted or unsubstituted cyclic imide group.

13. The method of claim 12, wherein the first histidine derivative is represented by Chemical Formula 1-1: 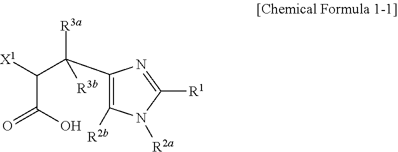
wherein, in Chemical Formula 1-1,
X¹ is a substituted or unsubstituted cyclic imide group,
R¹, R^{2a}, R^{2b}, R^{3a} and R^{3b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent R¹, R^{2a}, R^{2b}, R^{3a}, and R^{3b} are bonded to form a ring.

14. The method of claim 13, wherein X¹ in Chemical Formula 1-1 is a represented by any one of Chemical Formulas A to C: 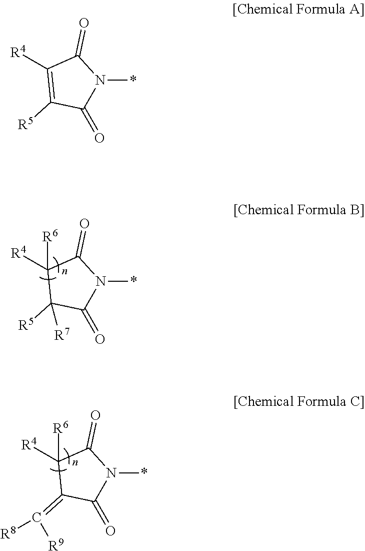
wherein, in Chemical Formulas A to C,
R⁴ to R⁹ are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴ to R⁹ are each independently present or any two adjacent R⁴ to R⁹ are bonded to form a ring,
n is an integer of 1 to 5, and
* is a linking point with Chemical Formula 1-1.

15. The method of claim 13, wherein X¹ in Chemical Formula 1-1 is represented by any one of Chemical Formulas B-1 to B-5: 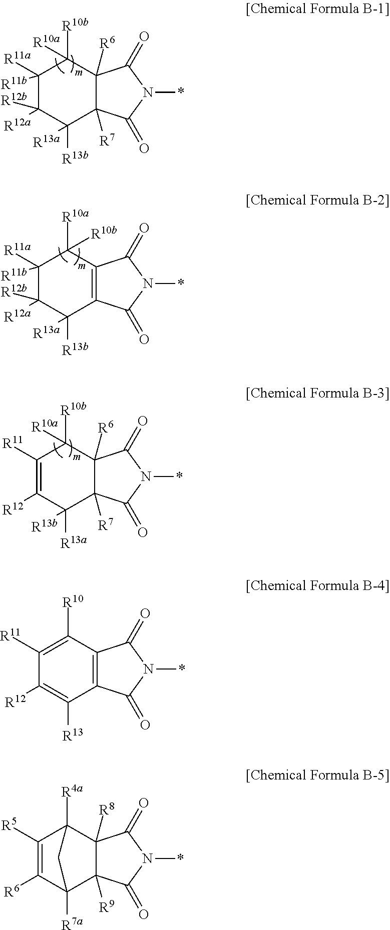
wherein, in Chemical Formulas B-1 to B-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently present or of two adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are bonded to form a ring,
m is an integer of 0 to 5, and
* is a linking point with Chemical Formula 1-1.

16. The method of claim 12, wherein the polishing slurry further comprises a second histidine derivative including a substituted or unsubstituted amic acid group.

17. The method of claim 16, wherein the second histidine derivative is represented by Chemical Formula 1-2: 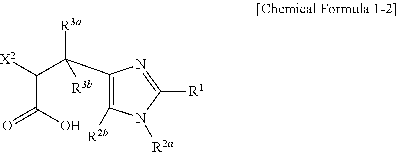
wherein, in Chemical Formula 1-2,
X² is a substituted or unsubstituted amic acid group,
R¹, R^{2a}, R^{2b}, R^{3a}, and R^{3b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent two R¹, R^{2a}, R^{2b}, R^{3a}, and R^{3b} of them are bonded to form a ring.

18. The method of claim 17, wherein X² in in Chemical Formula 1-2 is represented by any one of Chemical Formulas D to F. 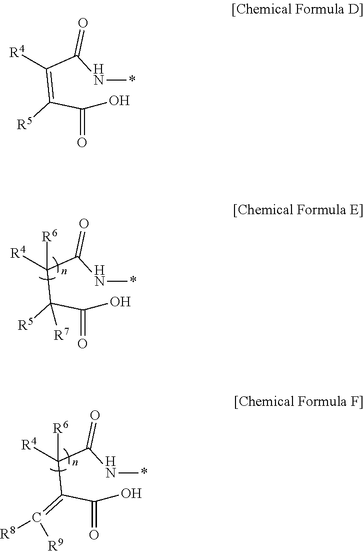
wherein, in Chemical Formulas D to F,
R⁴ to R⁹ are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴ to R⁹ are each independently present or any two adjacent R⁴ to R⁹ are bonded to form a ring,
n is an integer of 1 to 5, and
* is a linking point with Chemical Formula 1-2.

19. The method of claim 17, wherein X² in Chemical Formula 1-2 is represented by any one of Chemical Formulas E-1 to E-5: 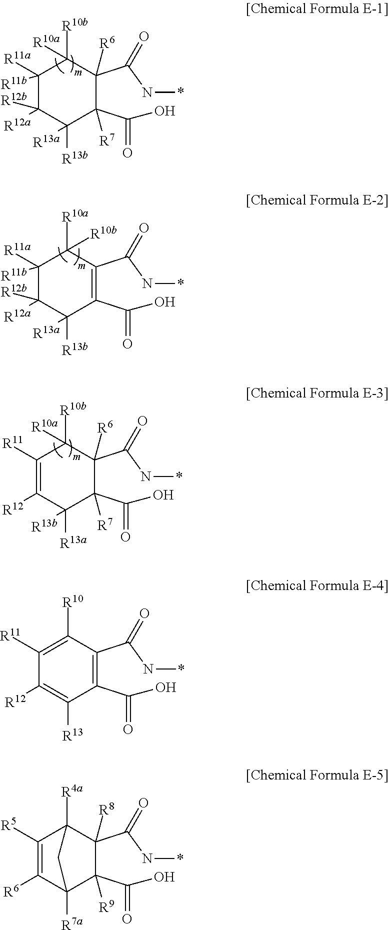
wherein, in Chemical Formulas E-1 to E-5,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are each independently present or any two adjacent R^{4a}, R⁵, R⁶, R⁷, R^{7a}, R⁸, R⁹, R¹⁰, R^{10a}, R^{10b}, R¹¹, R^{11a}, R^{11b}, R¹², R^{12a}, R^{12b}, R¹³, R^{13a}, and R^{13b} are bonded to form a ring,
m is an integer of 0 to 5, and
* is a linking point with Chemical Formula 1-2.

20. The method of claim 12, wherein the conductive layer comprises a molybdenum-containing layer.
